(19) United States
(12) Patent Application Publication
(10) Pub. No.: US 2007/0144706 A1
(43) Pub. Date: Jun. 28, 2007

(54) Heat sink and electronic equipment

(75) Inventor: Satoru Ohno, Osaka (JP)

Correspondence Address: NIXON & VANDERHYE, PC, 901 NORTH GLEBE ROAD, 11TH FLOOR, ARLINGTON, VA, 22203, US

(73) Assignee: Sharp Kabushiki Kaisha, Osaka (JP)

(21) Appl. No.: 11/429,261

(22) Filed: May 8, 2006

(30) Foreign Application Priority Data
Dec. 28, 2005 (JP) 2005-378791

(51) Int. Cl. H05K 7/20

(52) U.S. Cl. 165/80.3; 361/710

(57) ABSTRACT

A heat sink for radiating heat of an electronic component is provided with a heat sink main body having an abutting face that abuts against the electronic component, and a heat-radiation member having a joint face that is jointed to a front side face opposite to the abutting face. Furthermore, the heat-radiation member is provided with a joint portion that has the joint face, and a heat-radiation portion that is projectively provided so as to be substantially perpendicular to the joint portion. Furthermore, the heat-radiation member is provided with a plurality of heat-radiation portions.

### BACKGROUND OF THE INVENTION

This application claims priority under 35 U.S.C. § 119(a) on Patent Application No. 2005-378791 filed in Japan on Dec. 28, 2005, the entire contents of which are hereby incorporated by reference.

The present invention relates to a heat sink having a structure in which it is possible to easily change the heat-radiation capacity, and electronic equipment that is provided with such a heat sink.

A heat sink is mounted on the back face of an electronic component, and has a function to radiate heat so as to prevent the temperature of the electronic component from being equal to or higher than a prescribed temperature. Thus, the heat sink is molded by die-casting or extrusion using a metal having a high thermal conductivity as a material.

FIG. 12 is a perspective view of a conventional heat sink. In order to achieve a high heat-radiation efficiency, heat-radiation portions 125 are formed on a heat sink main body 112 of a heat sink 100. The heat-radiation portions 125 are formed so as to project from the heat sink main body 112, and thus the area in contact with air is increased, so that the function to improve the heat-radiation efficiency is provided.

In order to form the heat-radiation portions 125 that project from the heat sink main body 112, the heat sink 100 is formed by die-casting or extrusion. In die casting, molding is performed by letting molten metal flow into a mold. In extrusion, molding is performed by extruding an aluminum alloy or other materials from a mold. In either method, the heat sink main body 112 and the heat-radiation portions 125 are molded in one piece.

However, the heat sink 100 produced in these methods has a problem in that it is impossible to easily change the heat-radiation capacity. When there is a need to change the heat-radiation capacity, it is necessary to increase or decrease the heat-radiation portions 125, and thus it is necessary to manufacture a new mold. Accordingly, even when a change in the heat generation amount or other factors of the electronic component create a need to adjust the heat-radiation capacity, it is necessary to wait for a mold to be manufactured.

Furthermore, in order to manufacture a new heat sink 100, it is necessary to manufacture a new mold. Thus, in the case of small-lot production, the unit price of the product becomes high.

Thus, as the heat sink 100 in which it is possible to easily change the heat-radiation capacity, a heat sink 100 that is provided with fitting portions has been proposed (see Japanese Utility Model Publication H04-2047, for example). The heat sink 100 has a structure in which the fitting portions are provided, and it is possible to change the heat-radiation capacity by coupling the fitting portions.

However, according to the technique described in Japanese Utility Model Publication H04-2047, although it is possible to easily change the heat-radiation capacity, there is a problem in that the mounting area of the heat sink itself becomes large. Thus, since the heat sink occupies a considerable mounting area on the mounting board, there is a problem in that the area on which an electronic component can be mounted is decreased.

### SUMMARY OF THE INVENTION

The present invention was arrived at in view of these circumstances, and it is an object thereof to provide a heat sink having a structure in which it is possible to easily modify heat-radiation portions, and electronic equipment that is provided with such a heat sink.

In order to achieve the object, a heat sink according to the present invention is a heat sink for radiating heat of an electronic component, comprising: a heat sink main body having an abutting face that abuts against the electronic component, and a heat-radiation member having a joint face that is jointed to a front side face opposite to the abutting face.

With this configuration, the heat sink main body and the heat-radiation member are formed as separate members, and thus in the heat sink, it is possible to select the heat-radiation member in an appropriate shape and to provide an appropriate number of the heat-radiation members in accordance with the heat-radiation capacity. Furthermore, it is possible to select the heat-radiation member in an appropriate shape and to change the position of the heat-radiation member as appropriate in accordance with the space in which the heat sink is mounted. Accordingly, even in a case where the heat generation amount of the electronic component is changed or a space in which the heat sink is mounted is newly limited, it is possible to supply an appropriate heat sink as appropriate by easily and promptly changing the shape of the heat sink or the heat-radiation capacity.

Furthermore, the heat-radiation member is provided on the front side face of the heat sink main body, and thus the mounting area of the heat sink does not change. Accordingly, even when the heat-radiation capacity is increased, it is not necessary to newly provide a portion, on the mounting board, on which the heat sink is mounted.

Furthermore, in the heat sink according to the present invention, it is also possible that the heat-radiation member is provided with a joint portion that has the joint face, and a heat-radiation portion that is projectively provided so as to be substantially perpendicular to the joint portion.

With this configuration, the heat sink main body and the heat-radiation member are jointed to each other via the joint portion, and thus the jointed area becomes large, so that the heat transfer efficiency from the heat sink main body to the heat-radiation member is improved, and, as a result, the heat-radiation is improved. Furthermore, the joint portion is provided so as to be substantially perpendicular to the heat-radiation portion, and thus the heat-radiation member does not fall down when the heat-radiation member is jointed, so that the production can be stably performed. In addition, the jointed area is large, so that the joint strength is high.

Furthermore, in the heat sink according to the present invention, it is also possible that the heat-radiation member is provided with a plurality of heat-radiation portions. With this configuration, when one heat-radiation member is jointed to the heat sink main body, a plurality of heat-radiation portions are provided at a time, and thus the production efficiency is improved. Furthermore, it is possible to reduce the number of components of the heat sink.

Furthermore, in the heat sink according to the present invention, it is also possible that a plurality of heat-radiation members are provided, and the heat-radiation members are stacked and jointed to each other at the joint portions. With this configuration, it is possible to make the spacing between the heat-radiation portions small, and thus it is possible to make the heat-radiation capacity large.

Furthermore, in the heat sink according to the present invention, it is also possible that an engaging component for engaging the heat sink main body and the heat-radiation member is provided.

With this configuration, the heat sink main body and the heat-radiation member can be easily engaged with each other using the engaging component.

Furthermore, in the heat sink according to the present invention, it is also possible that a through hole passing through the heat sink main body and the heat-radiation member is formed, and the engaging component is inserted into the through hole and is plastically deformed to press the front side face and the joint face against each other.

With this configuration, the engaging component is plastically deformed to press the front side face and the joint face against each other, and thus it is possible to reliably transmit heat of the heat sink main body to the heat-radiation member. In addition, the heat sink main body and the heat-radiation member are engaged with each other on a portion other than the side faces, and thus no component projects from the side faces of the heat sink, so that the mounting area does not become large.

Furthermore, in the heat sink according to the present invention, it is also possible that a through hole passing through the heat sink main body and the heat-radiation member is formed, the engaging component is provided with a male engaging component, and a fitting component fitted so as to be capable of being attached to and detached from the male engaging component, and the male engaging component is inserted into the through hole and is fitted to the fitting component to press the front side face and the joint face against each other.

With this configuration, when the male engaging component is fitted to the fitting component, the front side face and the joint face are pressed against each other, and thus it is possible to reliably transmit heat of the heat sink main body to the heat-radiation member. In addition, the heat sink main body and the heat-radiation member are engaged with each other on a portion other than the side faces, and thus no component projects from the side faces of the heat sink, so that the mounting area does not become large.

Furthermore, the fitting component can be attached and detached, and thus it is possible to easily remove the heat-radiation member. With this configuration, it is possible to easily change the heat-radiation capacity.

Furthermore, in the heat sink according to the present invention, it is also possible that the heat sink main body has a main body engaging portion that is plastically deformed to be engaged with the joint portion.

With this configuration, the heat-radiation member can be engaged with the heat sink main body simply by deforming the main body engaging portion. Accordingly, it is possible to easily assemble the heat sink. Furthermore, there is no need for a component for coupling the heat sink main body and the heat-radiation member, and thus it is possible to reduce the number of assembling components.

Furthermore, in the heat sink according to the present invention, it is also possible that the heat-radiation member has a member engaging portion that is plastically deformed to be engaged with the heat sink main body.

With this configuration, the heat-radiation member can be engaged with the heat sink main body simply by deforming the member engaging portion. Accordingly, assembly in the production becomes easy. Furthermore, there is no need for a component for coupling the heat sink main body and the heat-radiation member, and thus it is possible to reduce the number of assembling components.

Furthermore, in the heat sink according to the present invention, it is also possible that the heat-radiation member has a projectively engaging portion formed so as to project from the joint face, and the heat sink main body has a fitting portion that is fitted to the projectively engaging portion.

With this configuration, the heat-radiation member can be engaged with the heat sink main body simply by inserting the projectively engaging portion into the fitting portion. Accordingly, assembly in the production becomes easy. Furthermore, there is no need for a component for coupling the heat sink main body and the heat-radiation member, and thus it is possible to reduce the number of assembling components.

Furthermore, in the heat sink according to the present invention, it is also possible that the heat-radiation member is jointed to the heat sink main body by welding. With this configuration, the heat-radiation member is not easily removed from the heat sink main body.

Furthermore, in the heat sink according to the present invention, it is also possible that the heat-radiation member is adhered to the heat sink main body using a thermal conductive adhesive.

With this configuration, it is possible to joint the heat sink main body and the heat-radiation member without a need for the engaging component and without a need to form the engaging portion on the heat sink main body or the heat-radiation member.

Furthermore, in the heat sink according to the present invention, it is also possible that the heat-radiation member is adhered to the heat sink main body using an elastic thermal conductive resin.

With this configuration, even when the difference in thermal expansion is generated between the heat sink main body and the heat-radiation member, and thus the stress occurs at the adhered portion, the stress is relaxed by the elastic thermal conductive resin. Accordingly, it is possible to prevent the adhered portion from being cut.

Furthermore, in the heat sink according to the present invention, it is also possible that the heat sink main body and the heat-radiation member are individually formed by die-casting. With this configuration, the precision in the dimensions of the heat sink main body and the heat-radiation member becomes high. Furthermore, the production by die-casting can be performed in a short time, and thus a large amount of supply can be achieved.

Furthermore, in the heat sink according to the present invention, it is also possible that the heat sink main body and the heat-radiation member are individually formed by extrusion. With this configuration, it is possible to manufacture a mold at a lower cost than that in die casting, and thus the initial cost can be made low. Furthermore, extrusion is suitable also for mass production, and thus the unit price of the heat sink can be made low.

Furthermore, in the heat sink according to the present invention, it is also possible that the heat sink main body and the heat-radiation member are formed by a sheet metal. With this configuration, there is no need for a mold, and thus the initial cost can be made low when a new heat sink is produced. Accordingly, the unit price of the heat sink can be made low in small-lot production.

Electronic equipment according to the present invention is electronic equipment provided with an electronic component that generates heat due to turn on electricity, wherein the heat sink according to the present invention is jointed to the electronic component.

With this configuration, the heat sink that fits the heat-radiation capacity of electronic component to which the heat sink is jointed is jointed to the electronic component, and thus the electronic equipment becomes thermally stable. The heat sink that fits each electronic component is produced almost without a need for the initial cost, and thus the cost of the electronic equipment can be made low.

### BRIEF DESCRIPTION OF THE DRAWINGS

FIG. 1 shows structural diagrams of a heat sink according to Embodiment 1 of the present invention, wherein FIG. 1A is a plan view and FIG. 1B is a side view.

FIG. 2 shows structural diagrams of a heat sink according to Embodiment 2 of the present invention, wherein FIG. 2A is a plan view and FIG. 2B is a side view.

FIG. 3 shows structural diagrams of a heat sink according to Embodiment 3 of the present invention, wherein FIG. 3A is a plan view and FIG. 3B is a cross-sectional view when viewed from the direction of the arrows A in FIG. 3A.

FIG. 4 shows structural diagrams of a heat sink according to Embodiment 4 of the present invention, wherein FIG. 4A is a plan view and FIG. 4B is a cross-sectional view when viewed from the direction of the arrows B in FIG. 4A.

FIG. 5 shows structural diagrams of a heat sink according to Embodiment 5 of the present invention, wherein FIG. 5A is a plan view and FIG. 5B is a side view.

FIG. 6 is a cross-sectional view when viewed from the direction of the arrows C in FIG. 5A.

FIG. 7 shows structural diagrams of a heat sink according to Embodiment 6 of the present invention, wherein FIG. 7A is a plan view, FIG. 7B is a side view, and FIG. 7C is a cross-sectional view when viewed from the direction of the arrows D in FIG. 7A.

FIG. 8 is an explanatory diagram from the side face in FIG. 7A, illustrating a manner in which a heat-radiation member and a heat sink main body according to Embodiment 6 of the present invention are assembled.

FIG. 9 shows structural diagrams of a heat sink according to Embodiment 7 of the present invention, wherein FIG. 9A is a plan view and FIG. 9B is a side view.

FIG. 10 shows structural diagrams of a heat sink according to Embodiment 8 of the present invention, wherein FIG. 10A is a plan view and FIG. 10B is a side view.

FIG. 11 shows structural diagrams of a heat sink according to Embodiment 9 of the present invention, wherein FIG. 11A is a plan view and FIG. 11B is a side view.

FIG. 12 is a perspective view of a conventional heat sink.

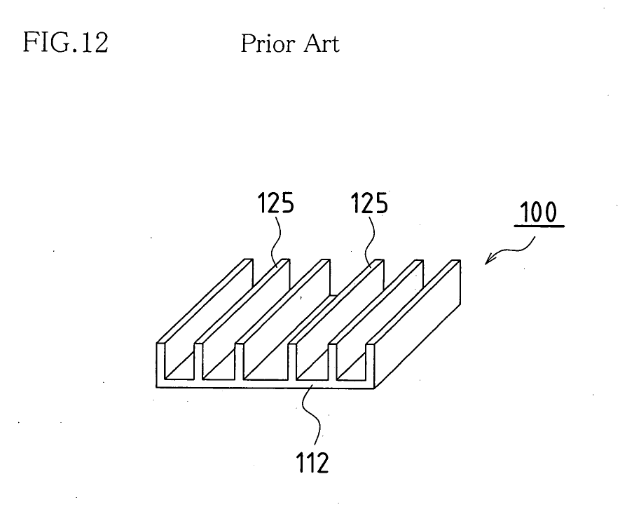

### DESCRIPTION OF THE PREFERRED EMBODIMENTS

Hereinafter, embodiments of the present invention will be described with reference to the drawings.

### Embodiment 1

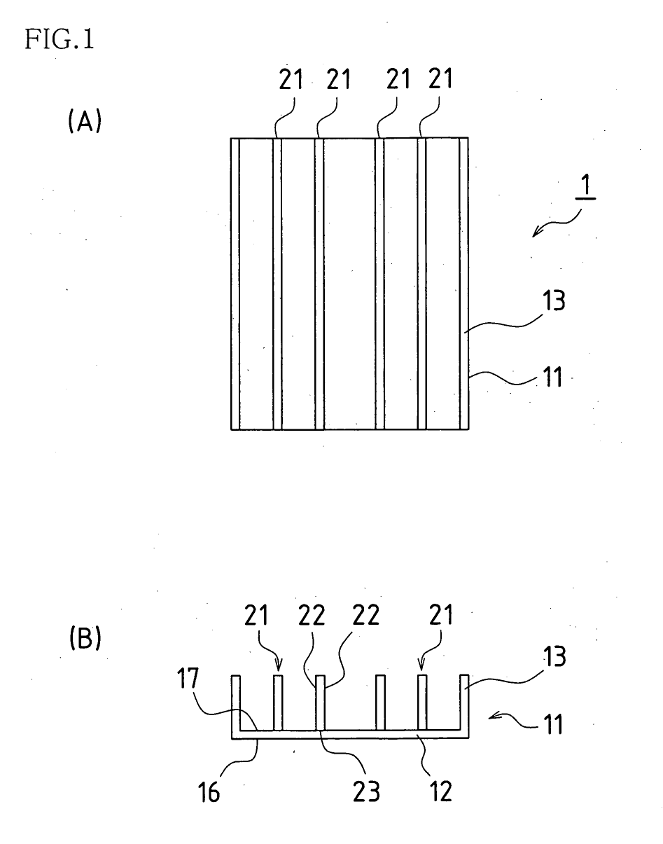

FIG. 1 shows structural diagrams of a heat sink according to Embodiment 1 of the present invention, wherein FIG. 1A is a plan view and FIG. 1B is a side view.

A heat sink 1 according to this embodiment of the present invention has the main portion that is constituted by a heat sink main body 11 serving as the main body of the heat sink 1, and heat-radiation members 21 having a function to radiate heat by being in contact with air.

The heat sink main body 11 is configured such that a side portion 13 is provided on a plate-shaped main body portion 12. The back side face of the main body portion 12 serves as an abutting face 16 that abuts against an electronic component, and is formed in a flat shape. The side portion 13 is projectively provided on both end sides on a front side face 17, which is opposite to the back side face. Furthermore, the front side face 17, which is opposite to the back side face, is formed in a flat shape such that the heat-radiation members 21 are jointed thereto.

Furthermore, it is preferable that the external shape of the periphery of the heat sink main body 11 is substantially the same as or similar to the shape of the back face of an electronic component on which the heat sink 1 is mounted. Accordingly, it is possible to absorb heat from the entire back face of the electronic component. In addition, it is also possible to almost eliminate the mounting area of the heat sink 1 on the mounting board.

Furthermore, the heat sink main body 11 is molded by die-casting or extrusion using, as a material, a metal having a high thermal conductivity such as aluminum alloy, copper alloy, and stainless steel. It should be noted that the method for molding the heat sink main body 11 is not limited to die casting and extrusion, and it is also possible to perform molding, for example, by rolling a sheet metal. Furthermore, it is also possible to form the heat sink main body 11 by processing ceramics or other materials having a high heat-radiation.

Furthermore, the shape of the front side face of the heat sink main body 11 is not limited to a concave shape as shown in FIG. 1. More specifically, it suffices that there is a portion to which the heat-radiation members 21 are jointed, and thus it is also possible to provide convex portions for radiating heat as appropriate in a portion other than the portion on which the heat-radiation members 21 are arranged.

The heat-radiation members 21 are projectively provided on the front side face 17 of the heat sink main body 11. The heat-radiation members 21 have a function to absorb heat from the heat sink main body 11 and to radiate the heat from heat-radiation faces 22 in contact with air. More specifically, the heat-radiation members 21 improve the heat-radiation efficiency by increasing the surface area of the heat sink 1.

Furthermore, the heat-radiation members 21 are projectively provided individually after the heat sink main body 11 has been formed. The number and the arrangement of the heat-radiation members 21 that are projectively provided are determined in accordance with the heat-radiation capacity of the heat sink 1. Accordingly, it is possible to easily produce the heat sink 1 having a desired heat-radiation capacity.

The heat-radiation member 21 is plate-shaped, has the heat-radiation faces 22 for radiating heat on both faces, and has a joint face 23 that is substantially perpendicular to the heat-radiation faces 22. When the joint faces 23 are led to abut against the front side face 17 of the heat sink main body 11, the heat-radiation members 21 are projectively provided so as to be substantially perpendicular to the heat sink main body 11. Thus, it is possible to projectively provide the plurality of heat-radiation members 21 close to each other. Furthermore, it is possible to easily form a large number of heat-radiation faces 22.

It should be noted that the shape of the heat-radiation member 21 is not limited to a plate shape, and any shape can be used as long as it has the joint face 23, and it may be, for example, a cylindrical shape.

The heat sink 1 is mounted on the back face of the electronic component by adhering the heat sink 1 using heat-radiation silicone grease or other substances. The heat sink 1 absorbs heat generated by the electronic component, and radiates the heat from the heat-radiation faces 22 of the heat-radiation members 21 into air.

The heat sink 1 has a configuration in which the heat sink main body 11 and the heat-radiation members 21 are formed as separate members, and thus it is possible to select the heat-radiation members 21 in an appropriate shape and to provide an appropriate number of the heat-radiation members 21 in accordance with the heat-radiation capacity. Furthermore, it is possible to select the heat-radiation members 21 in an appropriate shape and to change the positions of the heat-radiation members 21 as appropriate in accordance with the space in which the heat sink 1 is mounted. Accordingly, even in a case where the heat generation amount of the electronic component on which the heat sink 1 is mounted is changed or a space in which the heat sink 1 is mounted is newly limited, it is possible to supply an appropriate heat sink 1 as appropriate by easily and promptly changing the shape of the heat sink 1 or the heat-radiation capacity.

Furthermore, the heat-radiation members 21 are provided on the front side face 17 of the heat sink main body 11, and thus the mounting area of the heat sink 1 does not change. Accordingly, even when the heat-radiation capacity is increased, it is not necessary to newly provide a portion, on the mounting board, on which the heat sink 1 is mounted.

### Embodiment 2

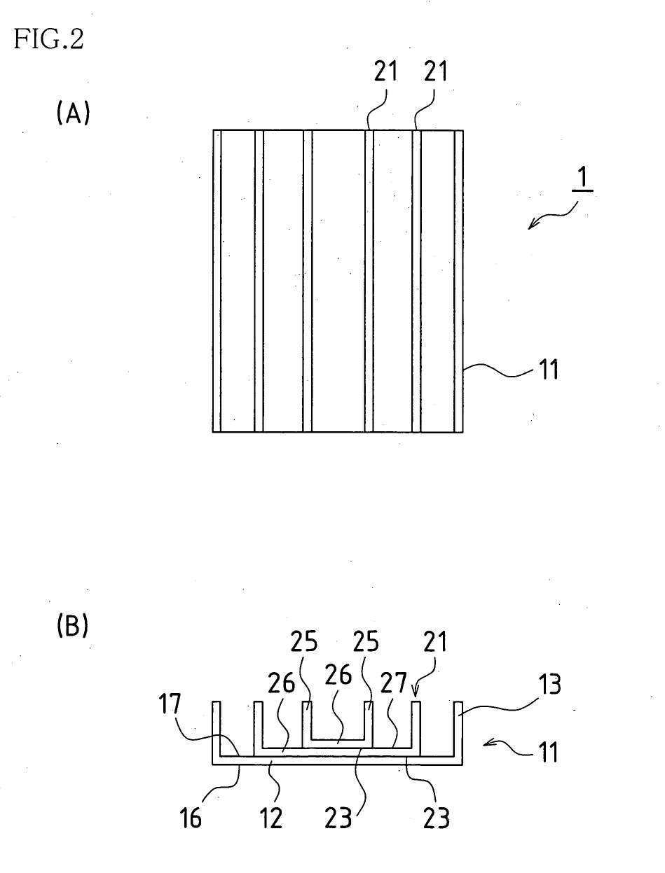

FIG. 2 shows structural diagrams of a heat sink according to Embodiment 2 of the present invention, wherein FIG. 2A is a plan view and FIG. 2B is a side view.

A heat sink 1 according to this embodiment of the present invention has the main portion that is constituted by a heat sink main body 11 abutting against an electronic component, and heat-radiation members 21 having a function to radiate heat by being in contact with air. The heat sink main body 11 is similar to that in Embodiment 1, and thus the description thereof has been omitted.

The heat-radiation member 21 is constituted by a joint portion 26 that is jointed to a front side face 17 of the heat sink main body 11, and heat-radiation portions 25 that are provided so as to be substantially perpendicular to the joint portion 26. One face of the joint portion 26 serves as a joint face 23 that is jointed to the front side face 17 of the heat sink main body 11. The joint face 23 is substantially flat, and thus the joint face 23 can be in close contact with the front side face 17 of the heat sink main body 11 or a front side face 27 of another heat-radiation member 21. Furthermore, the front side face 27 of the joint portion 26 is substantially flat, and thus another heat-radiation member 21 can be stacked on it. The heat-radiation portions 25 are projectively provided so as to be substantially perpendicular on both end sides on the front side face 27 of the joint portion 26.

It should be noted that the shape of the heat-radiation member 21 is not limited to a shape in which the two heat-radiation portions 25 are projectively provided, and the shape also may be such that if necessary, three or more heat-radiation portions 25 or one heat-radiation portion 25 is provided.

The heat sink main body 11 and the heat-radiation members 21 are jointed to each other via the joint portions 26, and thus the jointed area becomes large, so that the heat transfer efficiency from the heat sink main body 11 to the heat-radiation members 21 is improved, and, as a result, the heat-radiation is improved.

Furthermore, the joint portions 26 are provided so as to be substantially perpendicular to the heat-radiation portions 25, and thus the heat-radiation members 21 do not fall down when the heat-radiation members 21 are jointed, so that the production can be stably performed. In addition, the jointed area is large, so that the joint strength is high.

Furthermore, the heat-radiation member 21 can be jointed to the heat sink main body 11, or another heat-radiation member 21 can be further jointed on the heat-radiation member 21 that has been jointed. Thus, more options are provided in terms of the combination of the heat-radiation members 21, and thus it is possible to easily adjust the heat-radiation capacity.

### Embodiment 3

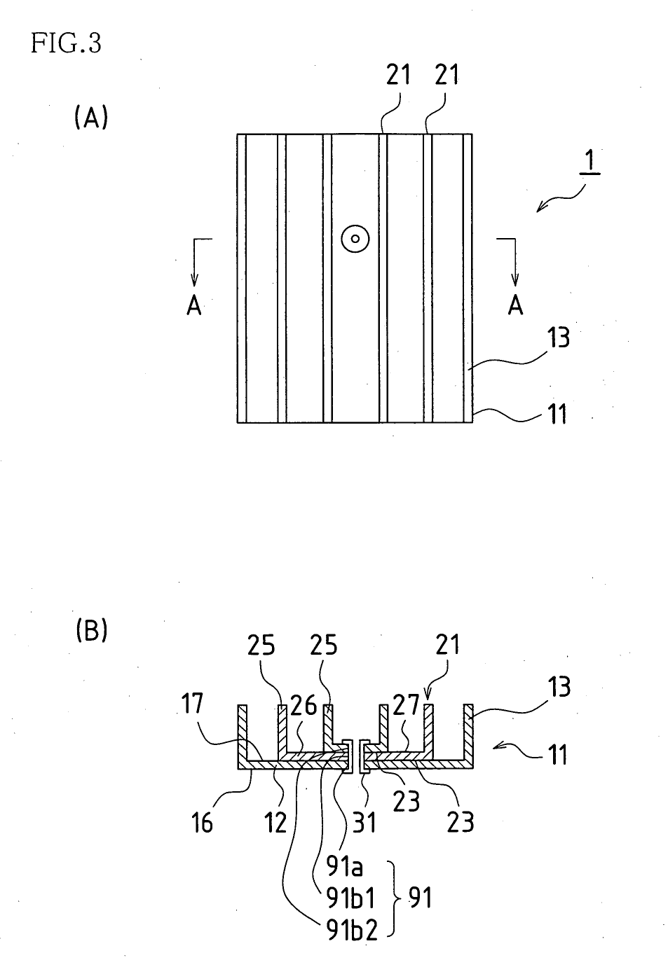

FIG. 3 shows structural diagrams of a heat sink according to Embodiment 3 of the present invention, wherein FIG. 3A is a plan view and FIG. 3B is a cross-sectional view when viewed from the direction of the arrows A in FIG. 3A.

A heat sink 1 according to this embodiment of the present invention has the main portion similar to that in Embodiment 2, and thus a detailed description thereof has been omitted. Herein, the joint structure between a heat sink main body 11 and heat-radiation members 21 is described.

In the heat sink 1, a portion on which a main body portion 12 of the heat sink main body 11 and joint portions 26 of the heat-radiation members 21 are stacked is provided with a through hole 91 that passes through the main body portion 12 and the joint portions 26. More specifically, the heat sink main body 11 and the heat-radiation members 21 are respectively provided with through holes 91A, and 91B1 and 91B2 having substantially the same cross-section, and the through holes 91A, 91B1 and 91B2 serve as one through hole 91 when the heat sink main body 11 and the heat-radiation members 21 are assembled. It should be noted that although FIGS. 3A and 3B show one through hole 91, the number is not limited to one and it is also possible to form a plurality of such through holes 91.

When a rivet (engaging component) 31 for pressing the heat sink main body 11 and the heat-radiation members 21 against each other is inserted into the through hole 91, and both ends of the rivet 31 are plastically deformed, the heat sink main body 11 and the heat-radiation members 21 are pressed so as to be engaged with each other. A screw, for example, is used as the rivet.

With this configuration, the heat sink main body 11 and the heat-radiation members 21 can be easily engaged with each other using the rivet 31. Furthermore, the rivet 31 is plastically deformed to press a front side face 17 of the heat sink main body 11 and joint faces 23 against each other, and thus it is possible to reliably transmit heat of the heat sink main body 11 to the heat-radiation members 21. In addition, the heat sink main body 11 and the heat-radiation members 21 are engaged with each other on a portion other than the side faces, and thus no component projects from the side faces of the heat sink 1, so that the mounting area does not become large.

### Embodiment 4

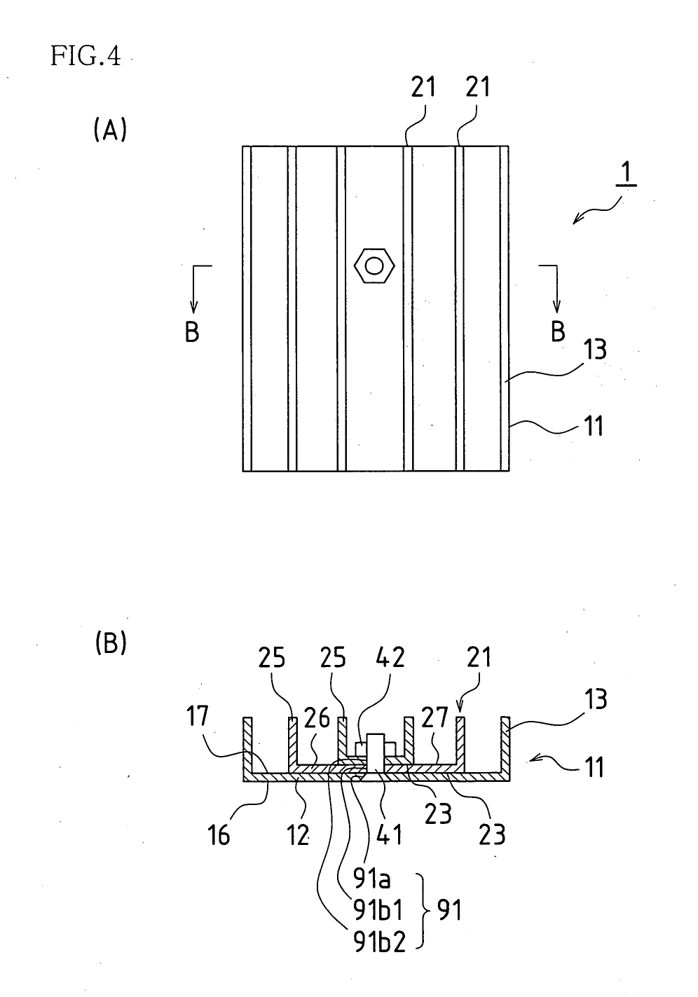

FIG. 4 shows structural diagrams of a heat sink according to Embodiment 4 of the present invention, wherein FIG. 4A is a plan view and FIG. 4B is a cross-sectional view when viewed from the direction of the arrows B in FIG. 4A.

A heat sink 1 according to this embodiment of the present invention has the main portion similar to that in Embodiment 2, and thus a detailed description thereof has been omitted. Herein, the joint structure between a heat sink main body 11 and heat-radiation members 21 is described.

In the heat sink 1, a portion on which a main body portion 12 of the heat sink main body 11 and joint portions 26 of the heat-radiation members 21 are stacked is provided with a through hole 91 that passes through the main body portion 12 and the joint portions 26. The heat sink main body 11 and the heat-radiation members 21 are respectively provided with through holes 91A, and 91B1 and 91B2 having substantially the same cross-section, and the through holes 91A, 91B1 and 91B2 serve as one through hole 91 when the heat sink main body 11 and the heat-radiation members 21 are assembled.

When a male engaging component 41 for pressing the heat sink main body 11 and the heat-radiation members 21 against each other is inserted into the through hole 91 and is fitted to a fitting component 42, the heat sink main body 11 and the heat-radiation members 21 are pressed to be engaged with each other. The fitting component 42 is configured such that the fitting component 42 can be attached to and detached from the male engaging component 41, and is fitted such that the fitting component 42 can be removed. A combination of a bolt and a nut, for example, is used as the male engaging component 41 and the fitting component 42.

With this configuration, the heat sink main body 11 and the heat-radiation members 21 can be easily engaged with each other simply by fitting the male engaging component 41 to the fitting component 42. Furthermore, when the male engaging component 41 is fitted to the fitting component 42, a front side face 17 of the heat sink main body 11 and joint faces 23 are pressed against each other, and thus it is possible to reliably transmit heat of the heat sink main body 11 to the heat-radiation members 21. In addition, the heat sink main body 11 and the heat-radiation members 21 are engaged with each other on a portion other than the side faces, and thus no component projects from the side faces of the heat sink 1, so that the mounting area does not become large.

Furthermore, the male engaging component 41 can be attached to and detached from the fitting component 42, and thus it is possible to easily remove the heat-radiation members 21. With this configuration, it is possible to easily change the heat-radiation capacity in the heat sink 1.

### Embodiment 5

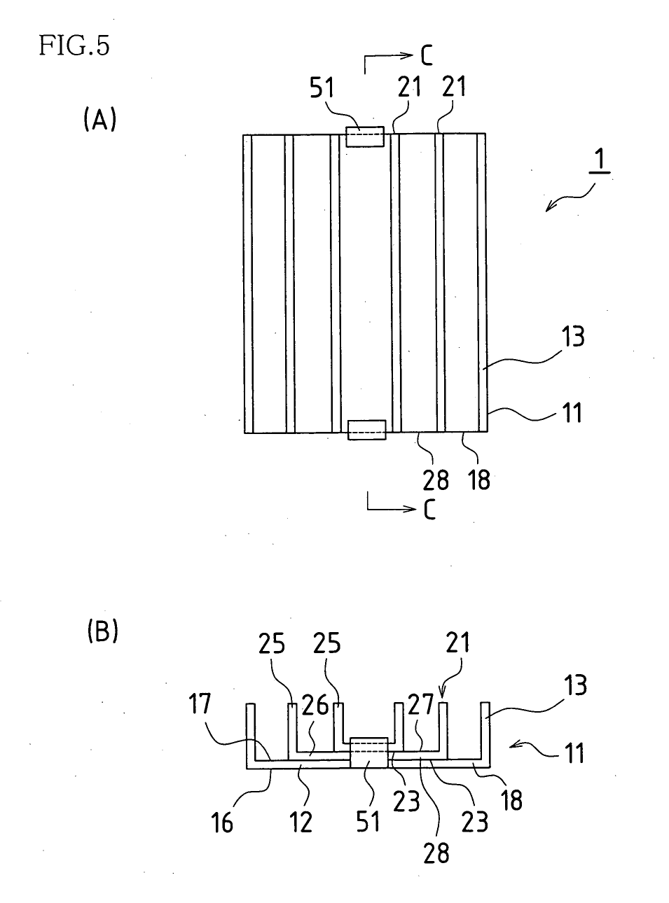

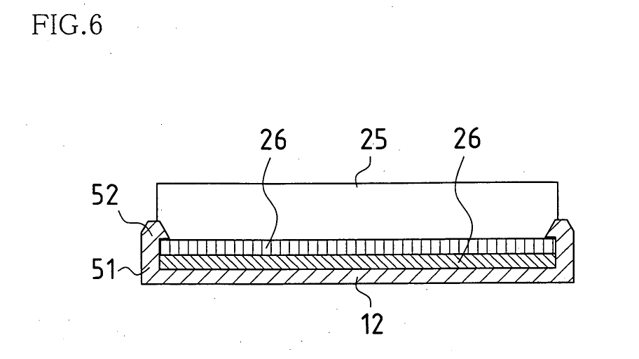

FIG. 5 shows structural diagrams of a heat sink according to Embodiment 5 of the present invention, wherein FIG. 5A is a plan view and FIG. 5B is a side view. FIG. 6 is a cross-sectional view when viewed from the direction of the arrows C in FIG. 5A.

A heat sink 1 according to this embodiment of the present invention has the main portion similar to that in Embodiment 2, and thus a detailed description thereof has been omitted. Herein, the joint structure between a heat sink main body 11 and heat-radiation members 21 is described.

The heat sink main body 11 and the heat-radiation members 21 are formed such that side faces 18 of the heat sink main body 11 and side faces 28 of the heat-radiation members 21 form flush surfaces when the heat sink main body 11 and the heat-radiation members 21 are stacked.

Furthermore, a main body engaging portion 51 that is engaged with joint portions 26 is provided on the side faces of the heat sink main body 11. The main body engaging portion 51 is formed such that front ends 52 are hook-shaped, and is plastically deformed to be pressed onto the joint portions 26. In addition, before the main body engaging portion 51 has been plastically deformed, the front ends 52 are open apart from a main body portion 12, and thus it is easy to stack the heat-radiation members 21.

It should be noted that it is also possible to provide a member engaging portion (not shown) on the side faces of the joint portions 26 of the heat-radiation members 21, instead of providing the main body engaging portion 51 on the heat sink main body 11. The member engaging portion is plastically deformed to couple the heat-radiation members 21 and the heat sink main body 11, and has the same structure as that of the main body engaging portion 51. For example, it is also possible that the member engaging portion is provided on the side faces of the heat-radiation member 21 that is stacked on the outermost side, and the member engaging portion is plastically deformed to press the stacked joint portions 26 onto the heat sink main body 11.

With this configuration, the heat-radiation members 21 can be engaged with the heat sink main body 11 simply by deforming the main body engaging portion 51 (or the member engaging portion). Accordingly, it is possible to easily assemble the heat sink 1. Furthermore, there is no need for a component for coupling the heat sink main body 11 and the heat-radiation members 21, and thus it is possible to reduce the number of assembling components.

### Embodiment 6

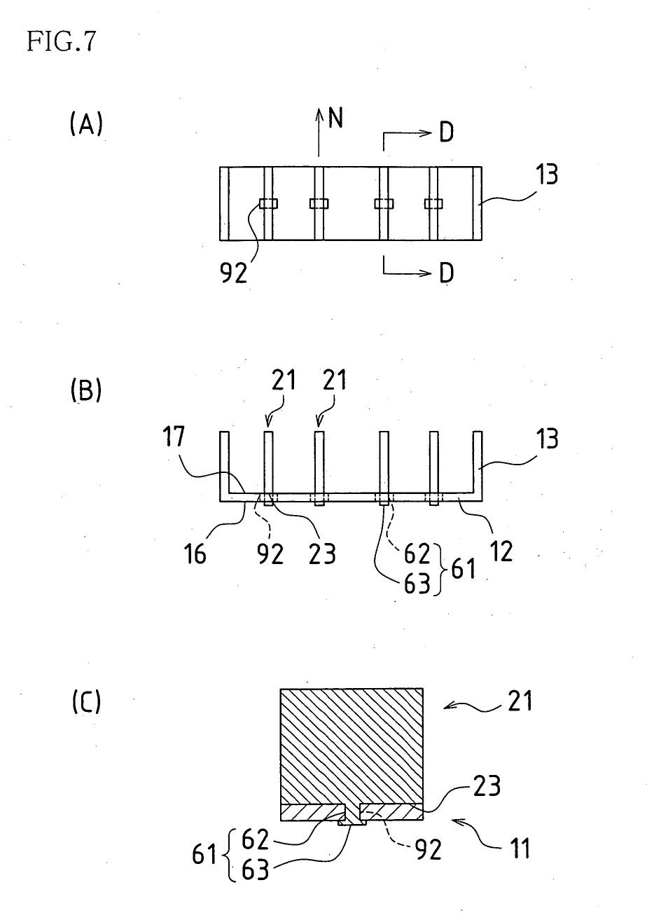

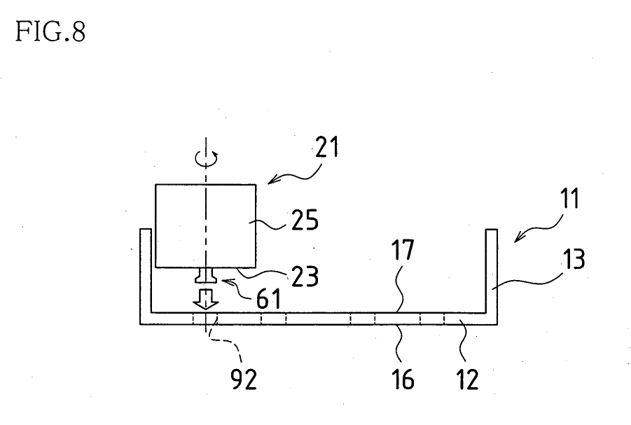

FIG. 7 shows structural diagrams of a heat sink according to Embodiment 6 of the present invention, wherein FIG. 7A is a plan view, FIG. 7B is a side view, and FIG. 7C is a cross-sectional view when viewed from the direction of the arrows D in FIG. 7A. FIG. 8 is an explanatory diagram from the side face in FIG. 7A, illustrating a manner in which a heat-radiation member and a heat sink main body according to Embodiment 6 of the present invention are assembled.

A heat sink 1 according to this embodiment of the present invention has the main portion similar to that in Embodiment 1 or 2, and thus a detailed description thereof has been omitted. Herein, the joint structure between a heat sink main body 11 and heat-radiation members 21 is described.

In the heat sink main body 11, a main body portion 12 is provided with a fitting portion 92. The fitting portion 92 is formed as a substantially rectangular through hole. Furthermore, a plurality of such fitting portions 92 are provided at predetermined locations on the main body portion 12, for example, they are provided at even intervals on one straight line, or provided on a grid. It should be noted that the shape of the fitting portions 92 is not limited to a rectangle.

The heat-radiation members 21 are formed such that projectively engaging portions 61 project from joint faces 23. The projectively engaging portion 61 is constituted by an intermediate portion 62 and a head portion 63. The intermediate portion 62 has a cross-section in the shape of a circle. The diameter of the circle is substantially equal to the narrowest width of the cross-section of the fitting portion 92. Furthermore, the length of the intermediate portion 62 is substantially equal to the depth of the fitting portion 92. The head portion 63 has the shape substantially the same as that of the fitting portion 92, and is formed so as to have the size in which the head portion 63 can pass through the fitting portion 92.

Furthermore, the longitudinal direction of the head portions 63 agrees with an arrangement direction N of the heat-radiation members 21. The fitting portions 92 are formed such that their longitudinal direction is a direction perpendicular to the arrangement direction N of the heat-radiation members 21. More specifically, when the projectively engaging portions 61 of the heat-radiation members 21 are inserted into the fitting portions 92, and the heat-radiation members 21 are rotated in a predetermined direction, the longitudinal direction of the head portions 63 does not agree with the longitudinal direction of the fitting portions 92. Thus, the heat-radiation members 21 are reliably engaged with the heat sink main body 11.

It should be noted that the arrangement of the longitudinal direction of the head portions 63 and the longitudinal direction of the fitting portions 92 is not limited to the directions in this embodiment. More specifically, it suffices that the longitudinal direction of the head portions 63 and the longitudinal direction of the fitting portions 92 are arranged so as not to be in agreement when the heat-radiation members 21 are rotated in a predetermined direction. For example, it is also possible that the head portions 63 are formed such that the longitudinal direction of the head portions 63 is perpendicular to the arrangement direction N of the heat-radiation members 21, while the fitting portions 92 are formed such that the longitudinal direction of the fitting portions 92 agrees with the arrangement direction N of the heat-radiation members 21. Thus, when the projectively engaging portions 61 of the heat-radiation members 21 are inserted into the fitting portions 92 and are rotated by 90 degrees, the longitudinal direction of the head portions 63 does not agree with the longitudinal direction of the fitting portions 92, and thus the heat-radiation members 21 are reliably engaged with the heat sink main body 11.

With this configuration, the heat-radiation members 21 can be engaged with the heat sink main body 11 by inserting the projectively engaging portions 61 into the fitting portions 92 and rotating the heat-radiation members 21. Accordingly, it is possible to easily assemble the heat sink 1. Furthermore, there is no need for a component for coupling the heat sink main body 11 and the heat-radiation members 21, and thus it is possible to reduce the number of assembling components.

Next, in Embodiments 7 to 9, joint between a heat sink main body 11 and heat-radiation members 21 achieved without structural engagement is described.

### Embodiment 7

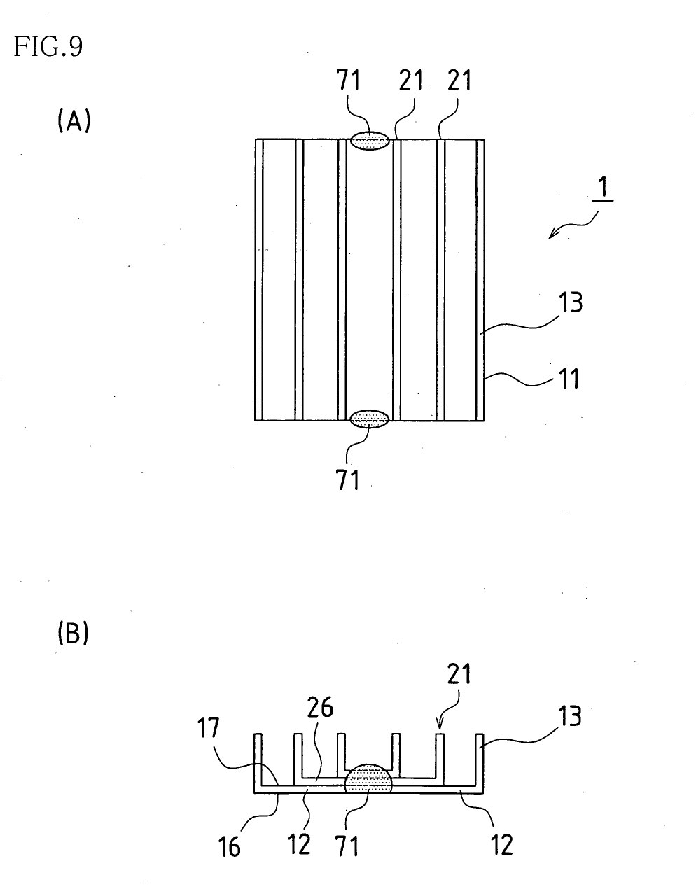

FIG. 9 shows structural diagrams of a heat sink according to Embodiment 7 of the present invention, wherein FIG. 9A is a plan view and FIG. 9B is a side view.

A heat sink 1 according to this embodiment of the present invention has the main portion similar to that in Embodiment 1 or 2, and thus a detailed description thereof has been omitted. Herein, joint between a heat sink main body 11 and heat-radiation members 21 is described.

The heat-radiation members 21 and the heat sink main body 11 are jointed to each other by welding. Welding is performed at locations 71 in which the side faces of the heat-radiation members 21 are in line with the side faces of the heat sink main body 11, and thus the plurality of heat-radiation members 21 are welded onto the heat sink main body 11 at a time. Accordingly, the heat-radiation members 21 are not easily removed from the heat sink main body 11.

### Embodiment 8

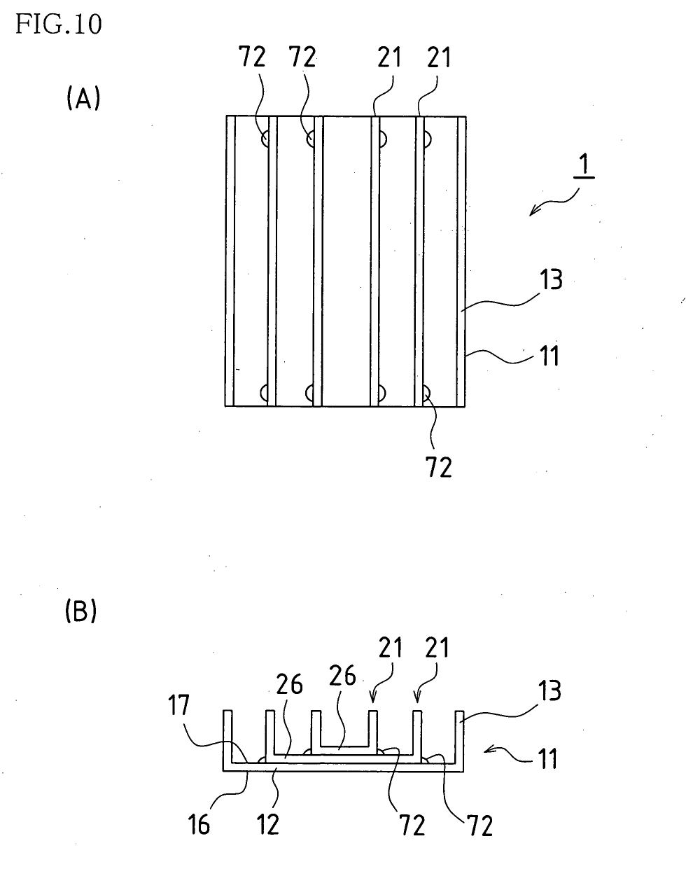

FIG. 10 shows structural diagrams of a heat sink according to Embodiment 8 of the present invention, wherein FIG. 10A is a plan view and FIG. 10B is a side view.

A heat sink 1 according to this embodiment of the present invention has the main portion similar to that in Embodiment 1 or 2, and thus a detailed description thereof has been omitted. Herein, joint between a heat sink main body 11 and heat-radiation members 21 is described.

The heat-radiation members 21 and the heat sink main body 11 are adhered to each other using a thermal conductive adhesive 72. Thus, it is possible to easily joint the heat sink main body 11 and the heat-radiation members 21, without a need for the engaging component 31 (see FIG. 3), and without a need to form the engaging portion on the heat sink main body 11 or the heat-radiation members 21.

### Embodiment 9

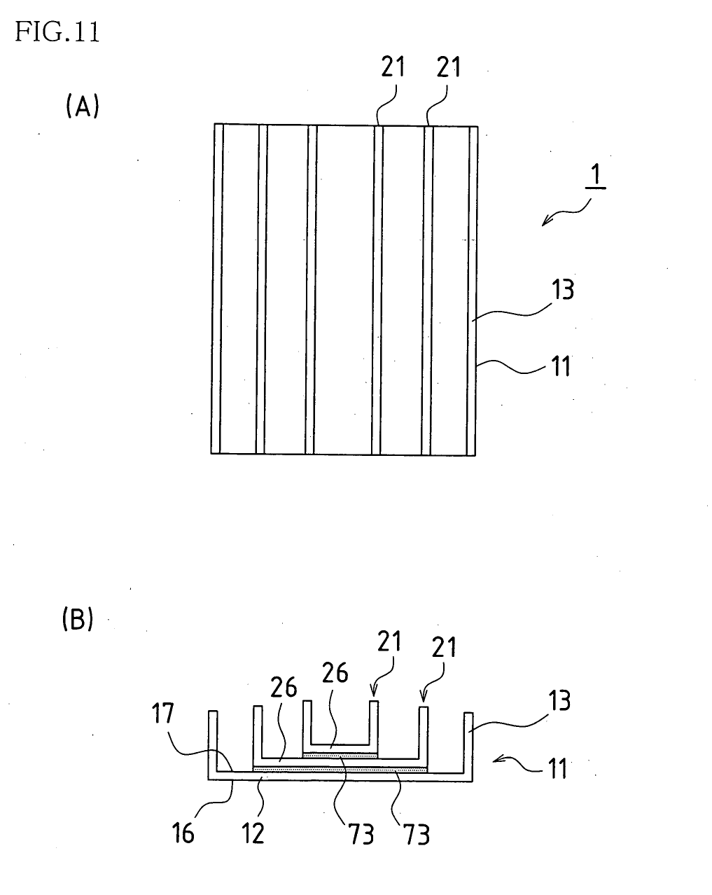

FIG. 11 shows structural diagrams of a heat sink according to Embodiment 9 of the present invention, wherein FIG. 11A is a plan view and FIG. 11B is a side view.

A heat sink 1 according to this embodiment of the present invention has the main portion similar to that in Embodiment 1 or 2, and thus a detailed description thereof has been omitted. Herein, joint between a heat sink main body 11 and heat-radiation members 21 is described.

The heat-radiation members 21 and the heat sink main body 11 are adhered to each other using an elastic thermal conductive resin 73. Thus, even when the difference in thermal expansion is generated between the heat sink main body 11 and the heat-radiation members 21, and thus the stress occurs at the adhered portions, the stress is relaxed by the elastic thermal conductive resin 73. Accordingly, it is possible to prevent the adhered portions from being cut.

### Embodiment 10

Referring to FIGS. 1 to 11, electronic equipment in which the heat sink 1 according to Embodiments 1 to 9 is mounted on an electronic component is described. It should be noted that the heat sink 1 mounted on the electronic component is not limited to the heat sink 1 according to Embodiments 1 to 9, and any heat sink may be used as long as it is a heat sink 1 provided with the configuration of the present invention.

The electronic equipment according to the present invention is provided with a power source portion and an electronic circuit for controlling the function of the electronic equipment. The electronic circuit is provided with a plurality of electronic components, and the heat sink 1 according to the present invention is mounted on an electronic component that may erroneously operate by generating heat due to the turn on electricity.

The heat sink 1 is fixed on the back face of the electronic component using a heat-radiation adhesive such as heat-radiation silicone. Furthermore, with respect to an electronic component for which it is necessary to perform appropriate heat-radiation design, the heat-radiation capacity of the heat sink 1 is set taking, into consideration, the operating temperature and the ambient temperature of the electronic component or other factors. The heat sink 1 is produced by jointing the heat-radiation members 21 to the heat sink main body 11 so as to fit the set heat-radiation capacity, and is mounted on the electronic component.

Accordingly, the heat sink 1 that fits the heat-radiation capacity of the electronic component is jointed to the electronic component, and thus the electronic equipment becomes thermally stable.

Furthermore, for the heat sink 1 that fits each of the electronic components, there is almost no need for the initial cost, and thus the cost of the electronic equipment can be made low.

The present invention can be embodied and practiced in other different forms without departing from the spirit and essential characteristics thereof. Therefore, the above-described embodiments are considered in all respects as illustrative and not restrictive. The scope of the invention is indicated by the appended claims rather than by the foregoing description. All variations and modifications falling within the equivalency range of the appended claims are intended to be embraced therein.

1. A heat sink for radiating heat of an electronic component, comprising:
a heat sink main body having an abutting face that abuts against the electronic component, and
a heat-radiation member having a joint face that is jointed to a front side face opposite to the abutting face.

2. The heat sink according to claim 1,
wherein the heat-radiation member is provided with a joint portion that has the joint face, and a heat-radiation portion that is projectively provided so as to be substantially perpendicular to the joint portion.

3. The heat sink according to claim 2,
wherein the heat-radiation member is provided with a plurality of heat-radiation portions.

4. The heat sink according to claim 2,
wherein a plurality of heat-radiation members are provided, and
the heat-radiation members are stacked and jointed to each other at the joint portions.

5. The heat sink according to claim 1, further comprising:
an engaging component for engaging the heat sink main body and the heat-radiation member.

6. The heat sink according to claim 5,
wherein a through hole passing through the heat sink main body and the heat-radiation member is formed, and
the engaging component is inserted into the through hole and is plastically deformed to press the front side face and the joint face against each other.

7. The heat sink according to claim 5,
wherein a through hole passing through the heat sink main body and the heat-radiation member is formed,
the engaging component is provided with a male engaging component, and a fitting component fitted so as to be capable of being attached to and detached from the male engaging component, and
the male engaging component is inserted into the through hole and is fitted to the fitting component to press the front side face and the joint face against each other.

8. The heat sink according to claim 1′,
wherein the heat sink main body has a main body engaging portion that is plastically deformed to be engaged with the joint portion.

9. The heat sink according to claim 1,
wherein the heat-radiation member has a member engaging portion that is plastically deformed to be engaged with the heat sink main body.

10. The heat sink according to claim 1,
wherein the heat-radiation member has a projectively engaging portion formed so as to project from the joint face, and
the heat sink main body has a fitting portion that is fitted to the projectively engaging portion.

11. The heat sink according to claim 1,
wherein the heat-radiation member is jointed to the heat sink main body by welding.

12. The heat sink according to claim 1,
wherein the heat-radiation member is adhered to the heat sink main body using a thermal conductive adhesive.

13. The heat sink according to claim 1,
wherein the heat-radiation member is adhered to the heat sink main body using an elastic thermal conductive resin.

14. The heat sink according to claim 1,
wherein the heat sink main body and the heat-radiation member are individually formed by die-casting.

15. The heat sink according to claim 1,
wherein the heat sink main body and the heat-radiation member are individually formed by extrusion.

16. The heat sink according to claim 1,
wherein the heat sink main body and the heat-radiation member are formed by a sheet metal.

17. Electronic equipment provided with an electronic component that generates heat due to turn on electricity,
wherein the heat sink according to claim 1 is jointed to the electronic component.
